(19) United States
(12) Patent Application Publication
(10) Pub. No.: US 2026/0093151 A1
(43) Pub. Date: Apr. 2, 2026

(54) DISPLAY DEVICE

(71) Applicant: Japan Display Inc., Tokyo (JP)

(72) Inventors: Motochika YUKAWA, Tokyo (JP); Akihiro HANADA, Tokyo (JP); Takuo KAITOH, Tokyo (JP)

(73) Assignee: Japan Display Inc., Tokyo (JP)

(21) Appl. No.: 19/309,658

(22) Filed: Aug. 26, 2025

(30) Foreign Application Priority Data
Sep. 30, 2024 (JP) 2024-170380

(51) Int. Cl. G02F 1/1368; G02F 1/1362; H10D 86/40; H10D 86/60

(52) U.S. Cl. CPC G02F 1/13685; G02F 1/13624; G02F 1/136295; H10D 86/423; H10D 86/60

(57) ABSTRACT

A display device includes a gate electrode, an oxide semiconductor layer overlapping the gate electrode, a first insulating layer containing an organic insulating material over the oxide semiconductor layer, a pixel electrode over the first insulating layer, a first connection electrode electrically connected to the pixel electrode and in contact with the first insulating layer, and a second connection electrode electrically connecting the oxide semiconductor layer and the first connection electrode, and provided between the oxide semiconductor layer and the first connection electrode. The first connection electrode contains a transparent conductive oxide. The second connection electrode contains a metal material.

### CROSS-REFERENCE TO RELATED APPLICATION

This application claims the benefit of priority to Japanese Patent Application No. 2024-170380, filed on Sep. 30, 2024, the entire contents of which are incorporated herein by reference.

### FIELD

An embodiment of the present invention relates to a display device using an oxide semiconductor film.

### BACKGROUND

In recent years, a transistor using an oxide semiconductor film (hereinafter, it may be referred to as an “OS transistor” for convenience.) has been developed (for example, see Japanese laid-open patent publication Nos. 2014-146819 and 2015-159315). Similar to a transistor using an amorphous silicon film (hereinafter, it may be referred to as an “a-Si transistor” for convenience), the OS transistor has a simple structure and is formed through a low-temperature process. It is known that the OS transistor has a higher mobility and a very low off-state current compared to the a-Si transistor.

### SUMMARY

A display device according to an embodiment of the present invention includes a gate electrode, an oxide semiconductor layer overlapping the gate electrode, a first insulating layer containing an organic insulating material over the oxide semiconductor layer, a pixel electrode over the first insulating layer, a first connection electrode electrically connected to the pixel electrode and in contact with the first insulating layer, and a second connection electrode electrically connecting the oxide semiconductor layer and the first connection electrode, and provided between the oxide semiconductor layer and the first connection electrode. The first connection electrode contains a transparent conductive oxide. The second connection electrode contains a metal material.

A display device according to an embodiment of the present invention includes a gate electrode, an oxide semiconductor layer overlapping the gate electrode, a first insulating layer containing an organic insulating material over the oxide semiconductor layer, a pixel electrode over the first insulating layer, and a first connection electrode in contact with the first insulating layer, and connecting the oxide semiconductor layer and the pixel electrode. The oxide semiconductor layer is separated into at least two regions between the gate electrode and the first connection electrode. The at least two regions are electrically connected to each other through a second connection electrode. The first connection electrode contains a transparent conductive oxide. The second connection electrode contains a metal material.

A display device according to an embodiment of the present invention includes a gate electrode, an oxide semiconductor layer overlapping the gate electrode, a first insulating layer containing an organic insulating material over the oxide semiconductor layer, a pixel electrode over the first insulating layer, a first connection electrode in contact with the first insulating layer, and a second connection electrode covering the first connection electrode so that the first connection electrode is not in contact with the first insulating layer, and electrically connecting the first connection electrode and the pixel electrode. The first connection electrode contains a transparent conductive oxide. The second connection electrode contains a metal material.

### BRIEF DESCRIPTION OF DRAWINGS

FIG. 1 is a schematic plan view showing an overview of a display device according to an embodiment of the present invention.

FIG. 2 is a block diagram showing a circuit configuration of a display device according to an embodiment of the present invention.

FIG. 3 is a circuit diagram showing a pixel circuit of a pixel of a display device according to an embodiment of the present invention.

FIG. 4 is a schematic cross-sectional view showing a configuration of an array substrate of a display device according to an embodiment of the present invention.

FIG. 5 is a schematic plan view showing a configuration of an array substrate of a display device according to an embodiment of the present invention.

FIG. 6 is a plan view illustrating a layout of each layer in an array substrate of a display device according to an embodiment of the present invention.

FIG. 7 is a plan view illustrating a layout of each layer in an array substrate of a display device according to an embodiment of the present invention.

FIG. 8 is a plan view illustrating a layout of each layer in an array substrate of a display device according to an embodiment of the present invention.

FIG. 9 is a plan view illustrating a layout of each layer in an array substrate of a display device according to an embodiment of the present invention.

FIG. 10 is a plan view illustrating a layout of each layer in an array substrate of a display device according to an embodiment of the present invention.

FIG. 11 is a plan view illustrating a layout of each layer in an array substrate of a display device according to an embodiment of the present invention.

FIG. 12 is a plan view illustrating a layout of each layer in an array substrate of a display device according to an embodiment of the present invention.

FIG. 13 is a plan view illustrating a layout of each layer in an array substrate of a display device according to an embodiment of the present invention.

FIG. 14 is a plan view illustrating a layout of each layer in an array substrate of a display device according to an embodiment of the present invention.

FIG. 15 is a plan view illustrating a layout of each layer in an array substrate of a display device according to an embodiment of the present invention.

FIG. 16 is a plan view illustrating a layout of each layer in an array substrate of a display device according to an embodiment of the present invention.

FIG. 17 is a plan view illustrating a layout of each layer in an array substrate of a display device according to an embodiment of the present invention.

FIG. 18 is a schematic cross-sectional view showing a configuration of an array substrate of a display device according to an embodiment of the present invention.

FIG. 19 is a schematic plan view showing a configuration of an array substrate of a display device according to an embodiment of the present invention.

FIG. 20 is a schematic cross-sectional view showing a configuration of an array substrate of a display device according to an embodiment of the present invention.

FIG. 21 is a schematic plan view showing a configuration of an array substrate of a display device according to an embodiment of the present invention.

### DESCRIPTION OF EMBODIMENTS

When an OS transistor with a low off-state current in a high-resolution display device such as a head mounted display is used, the power consumption of the display device is suppressed and can be utilized for a long time. However, a high-resolution display device requires an increased number of pixels while maintaining the aperture ratio. Therefore, there are problems that are unique to a high-resolution display device. For example, the precision in processes of the display device limits patterns of films and a structure of the display device. As a result, a high-resolution display device using an OS transistor has a problem in which the OS transistor tends to have a depletion-type transistor characteristic.

In view of the above problems, an embodiment of the present invention can provide a display device including a transistor using an oxide semiconductor layer in which variations in transistor characteristics are suppressed. Further, an embodiment of the present invention can provide an array substrate for the display device.

Hereinafter, an embodiment of the present invention is described with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In the present specification and each of the drawings, the same symbols are assigned to the same components as those described previously with reference to the preceding drawings, and a detailed description thereof may be omitted as appropriate.

In the present specification and the like, a direction from a substrate toward an oxide semiconductor layer is referred to as “above” or “on.” Conversely, a direction from the oxide semiconductor layer to the substrate is referred to as “below” or “under.” For convenience of explanation, the term “above” or “below” is used for description, but for example, the substrate and the oxide semiconductor layer may be arranged so that the vertical relationship is reversed from that shown in the drawings. In the following explanation, for example, the expression “an oxide semiconductor layer on a substrate” merely describes the vertical relationship between the substrate and the oxide semiconductor layer as described above, and another member may be arranged between the substrate and the oxide semiconductor layer. The term “above” or “below” means a stacking order in which a plurality of layers is stacked, and may have a positional relationship in which an oxide semiconductor layer and a pixel electrode do not overlap in a plan view when expressed as “a pixel electrode above an oxide semiconductor layer.” On the other hand, the expression “a pixel electrode vertically above an oxide semiconductor layer” means a positional relationship in which the oxide semiconductor layer and the pixel electrode overlap in a plan view. In addition, a plan view refers to viewing from a direction perpendicular to a surface of the substrate.

In the present specification and the like, the expression “α includes A, B, or C,” “α includes any of A, B, or C,” or “α includes one selected from a group consisting of A, B and C,” and the like does not exclude the case where α includes a plurality of combinations of A to C unless otherwise specified. Further, these expressions do not exclude the case where α includes other components.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer is exemplified as a display device in the following embodiments, the structure according to the present embodiment can be applied to a display device including the other electro-optic layers described above.

In the present specification and the like, the terms “film” and “layer” can be optionally interchanged with one another.

In addition, the following embodiments can be combined with each other as long as there is no technical contradiction.

### First Embodiment

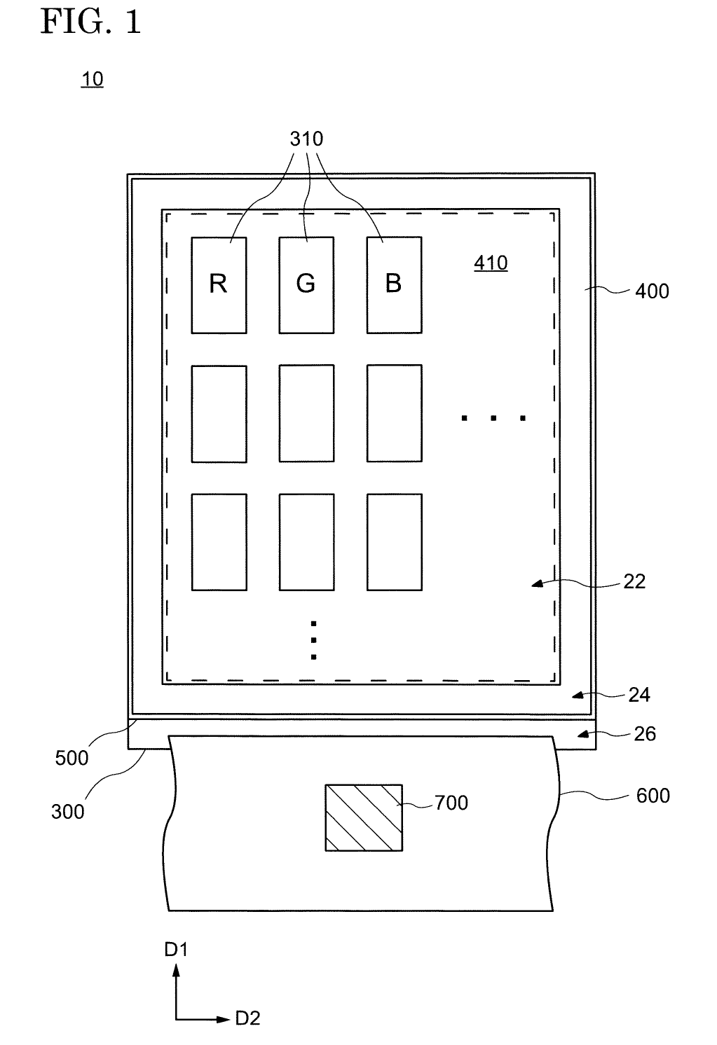

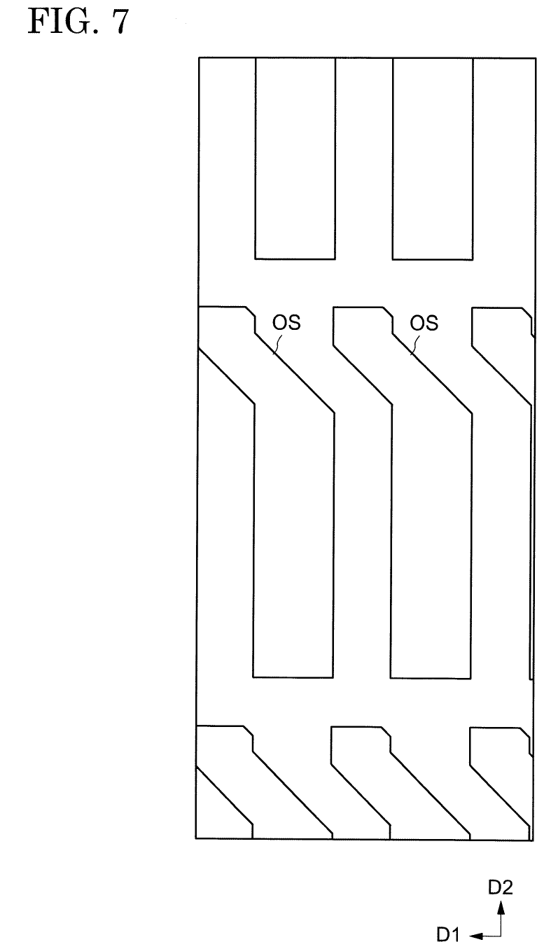

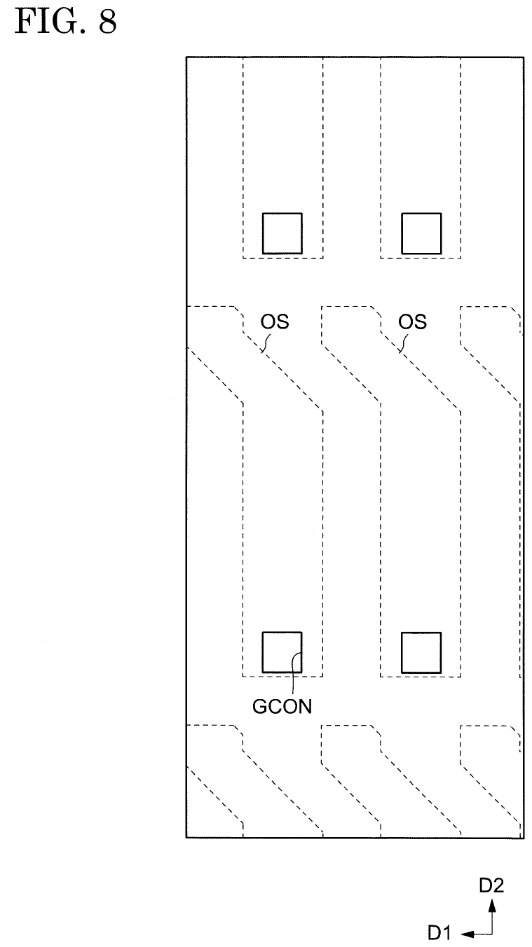

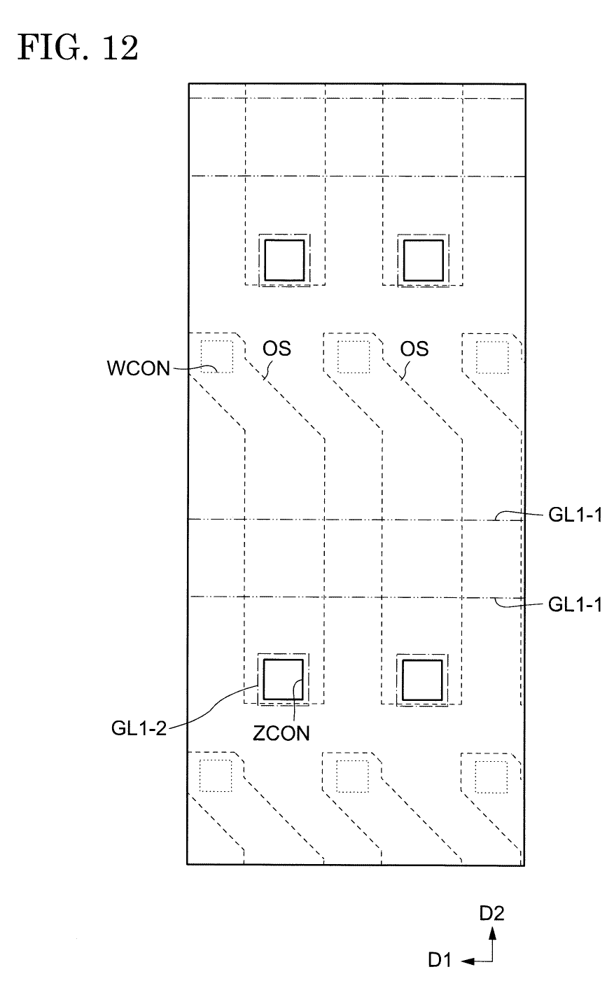

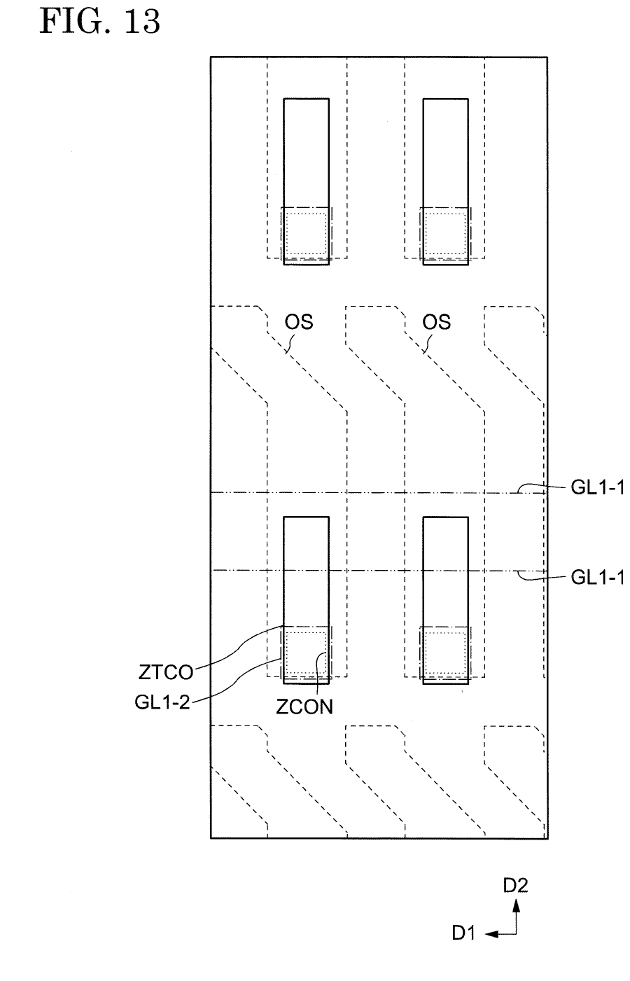

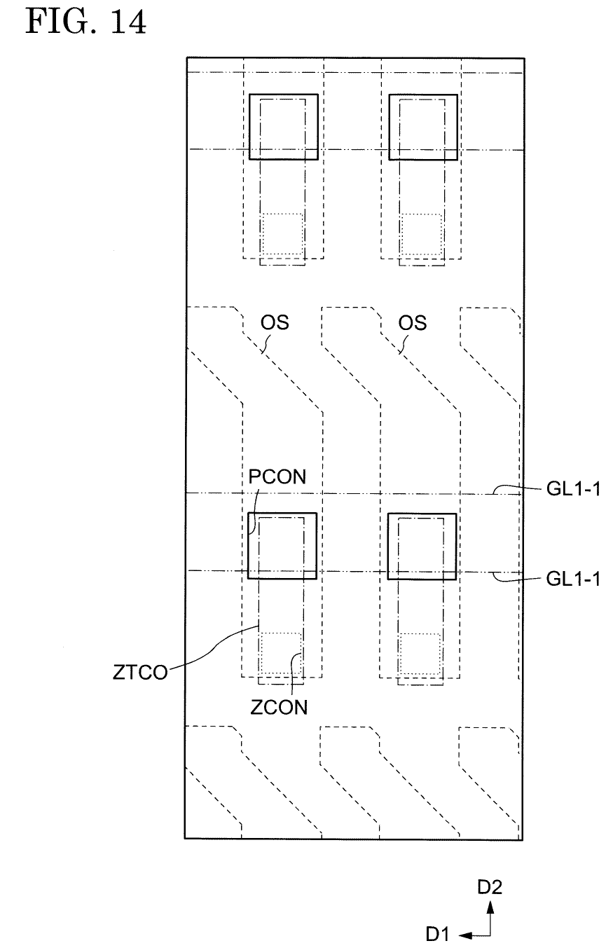

A configuration of a display device 10 according to an embodiment of the present invention is described with reference to FIGS. 1 to 17.

### [1. Overview of Display Device 10]

FIG. 1 is a schematic plan view illustrating an overview of a display device 10 according to an embodiment of the present invention. As shown in FIG. 1, the display device 10 includes an array substrate 300, a sealing member 400, a counter substrate 500, a flexible printed circuit (FPC) 600, and an IC chip 700. The array substrate 300 and the counter substrate 500 are disposed so as to face each other and are bonded together by the sealing member 400. The sealing member 400 is provided on the periphery of the counter substrate 500, and liquid crystal is sealed in the space surrounded by the array substrate 300, the counter substrate 500, and the sealing member 400. That is, a liquid crystal region 22 is formed inside a seal region 24 in which the sealing member 400 is provided. In the liquid crystal region 22, a plurality of pixels 310 are provided on the array substrate 300. The plurality of pixels 310 are arranged in a matrix in a first direction D1 (hereinafter, it may be referred to as a “column direction”) and a second direction D2 (hereinafter, it may be referred to as a “row direction”) orthogonal to the first direction D1. The first direction D1 and the second direction D2 may be perpendicular to each other. In the liquid crystal region 22, color filters are provided on the counter substrate 500 so as to correspond to the plurality of pixels 310. The plurality of pixels 310 are defined as a red pixel R, a green pixel G, and a blue pixel B according to the colors of the color filters.

The display device 10 has a backlight unit on the back of the array substrate 300. When light emitted from the backlight unit passes through the liquid crystal region 22, the transmitted light is modulated by the liquid crystal sealed in the liquid crystal region 22 in each pixel 310, and an image is displayed in the liquid crystal region 22. In addition, hereinafter, the region in the liquid crystal region 22 where the plurality of pixels 310 of the array substrate 300 are provided may be referred to as an “image display region.”

The FPC 600 is provided in a terminal region 26 of the array substrate 300 exposed from the counter substrate 500. That is, the terminal region 26 is provided outside the seal region 24. The IC chip 700 is provided on the FPC 600 and supplies signals for driving pixel circuits to each of the plurality of pixels 310. In addition, hereinafter, the seal region 24 and the terminal region 26 may be referred to as a “frame region.”

### [2. Circuit Configuration of Display Device 10]

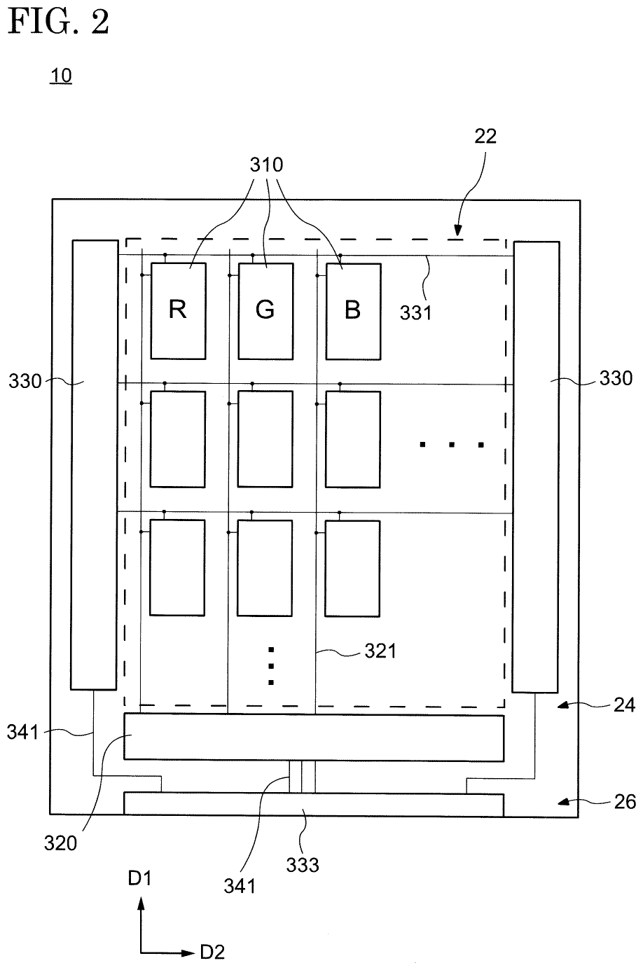

FIG. 2 is a block diagram showing a circuit configuration of the display device 10 according to an embodiment of the present invention. As shown in FIG. 2, a source driver circuit 320 is provided on the array substrate 300 at a position adjacent to the liquid crystal region 22 in the first direction D1, and a gate driver circuit 330 is provided on the array substrate 300 at a position adjacent to the liquid crystal region 22 in the second direction D2. That is, the source driver circuit 320 and the gate driver circuit 330 are provided in the seal region 24. However, the region in which the source driver circuit 320 and the gate driver circuit 330 are provided is not limited to the seal region 24, and may be a region outside the plurality of pixels 310 in the liquid crystal region 22.

A source wiring 321 extends from the source driver circuit 320 in the first direction D1 and is electrically connected to the pixel circuits of the plurality of pixels 310 arranged in the first direction D1. A gate wiring 331 extends from the gate driver circuit 330 in the second direction D2 and is electrically connected to the pixel circuits of the plurality of pixels 310 arranged in the second direction D2.

A terminal portion 333 is provided in the terminal region 26. The terminal portion 333 and the source driver circuit 320 are electrically connected to each other via a connection wiring 341. Similarly, the terminal portion 333 and the gate driver circuit 330 are electrically connected to each other via a connection wiring 341. A signal from an external device is input to the source driver circuit 320 and the gate driver circuit 330 via the FPC 600 and the terminal portion 333 provided in the terminal region 26. Thus, the pixel circuit of each of the multiple pixels 310 are driven.

### [3. Pixel Circuit of Pixel 310]

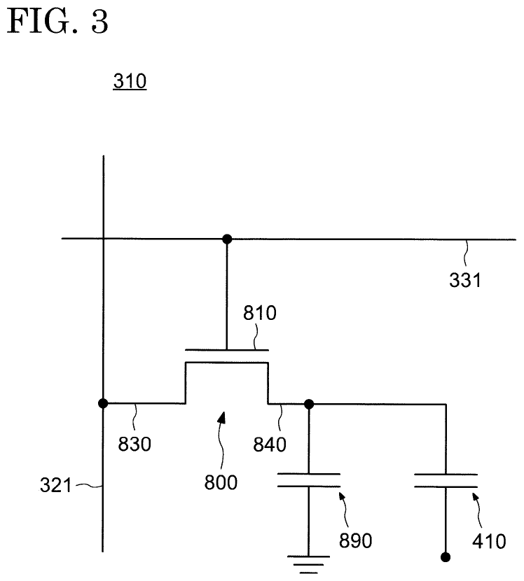

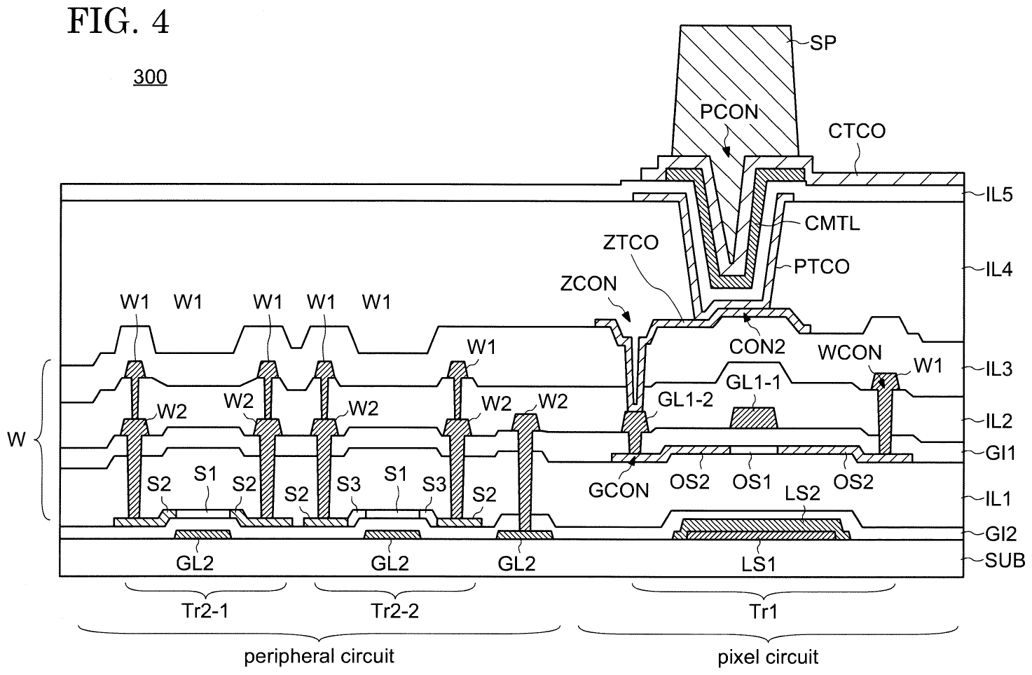

FIG. 3 is a circuit diagram showing a pixel circuit of the pixel 310 of the display device 10 according to an embodiment of the present invention. As shown in FIG. 3, the pixel circuit includes elements such as a transistor 800, a storage capacitor 890, and a liquid crystal element 410. Although details are described later, one electrode of the storage capacitor 890 is a pixel electrode PTCO, and the other electrode is a common electrode CTCO (see FIG. 4). Further, one electrode of the liquid crystal element 410 is a pixel electrode PTCO, and the other electrode is a common electrode CTCO (see FIG. 4). The transistor 800 includes a first gate electrode 810, a first source electrode 830, and a first drain electrode 840. The first source electrode 830 and the first drain electrode 840 function as a source and a drain, respectively. However, these functions may be reversed. The first gate electrode 810 is electrically connected to the gate wiring 331. The first source electrode 830 is electrically connected to the source wiring 321. The first drain electrode 840 is electrically connected to the storage capacitor 890 and the liquid crystal element 410.

### [4. Configuration of Array Substrate 300]

In the present embodiment, an OS transistor is used as the transistor 800. That is, the pixel circuit includes an OS transistor provided on the array substrate 300. In the following description, a configuration of the array substrate 300 is described with reference to FIGS. 4 to 16.

### [4-1. Components of Array Substrate 300]

FIG. 4 is a schematic cross-sectional view showing a configuration of the array substrate 300 of the display device 10 according to an embodiment of the present invention. In addition, FIG. 4 is a cross-sectional view for explaining the layer structure of the array substrate 300, in which the peripheral circuit and the pixel circuit are adjacent to each other. However, the pixel circuit and the peripheral circuit are provided in the image display region and the frame region, respectively, and are actually spaced apart from each other. Further, in order to explain the connection relationship between the layers in FIG. 4, the openings (contact holes) of the pixel circuits are mainly shown, and only a portion of the translucent region (opening region) that contributes to display is shown.

As shown in FIG. 4, the array substrate 300 includes multiple components, such as a transistor Tr1 and transistors Tr2-1 and Tr2-2 (hereinafter, they may be referred to as a “transistor Tr2” when they are not particularly distinguished), provided on a substrate SUB. Specifically, the array substrate 300 includes the transistor Tr1, the transistors Tr2-1 and Tr2-2, a wiring W, a connection electrode ZTCO, a pixel electrode PTCO, a common auxiliary electrode CMTL, and a common electrode CTCO. Here, TCO is an abbreviation for transparent conductive oxide. The transistor Tr1 is a transistor included in the pixel circuit. The transistor Tr2 is a transistor included in a peripheral circuit such as the source driver circuit 320 or the gate driver circuit 330.

### [4-2. Configuration of Transistor Tr1]

As shown in FIG. 4, the transistor Tr1 includes oxide semiconductor layers OS1 and OS2 (hereinafter, they may be referred to as an “oxide semiconductor layer OS” when they are not particularly distinguished), a gate insulating layer GI1, and a gate electrode GL1-1. That is, the transistor Tr1 is an OS transistor. The gate electrode GL1-1 overlaps the oxide semiconductor layer OS. The gate insulating layer GI1 is provided between the oxide semiconductor layer OS and the gate electrode GL1-1. In the present embodiment, although a top-gate transistor in which the oxide semiconductor layer OS is provided closer to the substrate SUB than the gate electrode GL1-1 is exemplified; a bottom-gate transistor in which the positional relationship between the gate electrode GL1-1 and the oxide semiconductor layer OS is reversed may also be used.

The oxide semiconductor layer OS is divided into oxide semiconductor layers OS1 and OS2 based on its conductivity. The oxide semiconductor layer OS1 overlaps the gate electrode GL1-1. The oxide semiconductor layer OS1 functions as a semiconductor layer and is switched between a conductive state and a non-conductive state depending on the voltage supplied to the gate electrode GL1-1. That is, the oxide semiconductor layer OS1 functions as a channel region of the transistor Tr1. On the other hand, the oxide semiconductor layers OS2 located on both sides of the oxide semiconductor layer OS1 function as conductive layers. That is, the oxide semiconductor layers OS2 function as a source region and a drain region. The oxide semiconductor layers OS1 and OS2 are one continuous layer. For example, when impurities are added into the oxide semiconductor layer OS1 functioning as a semiconductor layer, the oxide semiconductor layer OS2 can be reduced in resistance and functions as a conductive layer.

The gate insulating layer GI1 is provided on the oxide semiconductor layer OS. The gate electrode GL1-1 and the connection electrode GL1-2 are provided on the gate insulating layer GI1. The gate electrode GL1-1 and the connection electrode GL1-2 are the same layer formed by patterning a single deposited conductive film (here, the single conductive film may have a single-layer structure or a stacked structure). Therefore, the gate electrode GL1-1 and the connection electrode GL1-2 have the same material and the same structure. Although details are described later, a metal material is used for the gate electrode GL1-1 and the connection electrode GL1-2. As described above, the gate electrode GL1-1 is provided so as to overlap the oxide semiconductor layer OS1. On the other hand, the connection electrode GL1-2 is electrically connected to one of the oxide semiconductor layers OS2 through an opening GCON provided in the gate insulating layer GI1. The connection electrode GL1-2 is in contact with the oxide semiconductor layer OS2 at the bottom of the opening GCON.

An insulating layer IL2 is provided on the gate electrode GL1-1. A wiring W1 is provided on the insulating layer IL2. The wiring W1 is electrically connected to the other of the oxide semiconductor layers OS2 via an opening WCON provided in the insulating layer IL2 and the gate insulating layer GI1. A data signal related to the gradation of the pixel is transmitted to the wiring W1. An insulating layer IL3 is provided on the insulating layer IL2 and the wiring W1. In addition, the wiring W1 is not in contact with the insulating layer IL1. The connection electrode ZTCO is provided on the insulating layer IL3. Although details are described later, a transparent conductive oxide is used for the connection electrode ZTCO. The connection electrode ZTCO is electrically connected to the connection electrode GL1-2 via an opening ZCON provided in the insulating layers IL3 and IL2.

An insulating layer IL4 is provided on the connection electrode ZTCO. The insulating layer IL4 reduces steps formed by the layers provided below the insulating layer IL4. In other words, the insulating layer IL4 functions as a planarizing film. The pixel electrode PTCO is provided on the insulating layer IL4. Although details are described later, a transparent conductive oxide is used for the pixel electrode PTCO. The pixel electrode PTCO is electrically connected to the connection electrode ZTCO via an opening PCON provided in the insulating layer IL4.

An insulating layer IL5 is provided on the pixel electrode PTCO. The common auxiliary electrode CMTL and the common electrode CTCO are provided on the insulating layer IL5. Although details are described later, a metal material and a transparent conductive oxide are used for the common auxiliary electrode CMTL and the common electrode, respectively. The electrical resistance of the common auxiliary electrode CMTL is lower than the electrical resistance of the common electrode CTCO. The common auxiliary electrode CMTL also functions as a light shielding layer. For example, since the common auxiliary electrode CMTL blocks light from adjacent pixels, color mixing is suppressed. A spacer SP is provided on the common electrode CTCO.

The spacers SP are provided for some pixels. For example, the spacers SP may be provided for one of the red, green, and blue pixels. However, the spacers SP may also be provided for all pixels. The height of the spacers SP is half the height of the cell gap. Spacers are also provided on the counter substrate, and the spacers on the counter substrate and the spacers SP overlap each other in a planar view. In addition, a configuration in which the height of the spacers SP matches the cell gap can also be applied. Further, as shown in FIG. 4, although the spacer SP is filled in the opening PCON and protrudes toward the counter substrate, a configuration in which the opening PCON is simply filled with a filler can also be applied.

A light shielding layer LS is provided between the transistor Tr1 and the substrate SUB. In the present embodiment, light shielding layers LS1 and LS2 are provided as the light shielding layer LS. However, the light shielding layer LS may be formed of only one of the light shielding layers LS1 and LS2. In a plan view, the light shielding layer LS is provided so as to overlap the gate electrode GL1-1 and the oxide semiconductor layer OS. That is, in a plan view, the light shielding layer LS is provided so as to overlap the oxide semiconductor layer OS1. The light shielding layer LS prevents light incident from the substrate SUB side from reaching the oxide semiconductor layer OS1. When a conductive layer is used as the light shielding layer LS, a voltage may be applied to the light shielding layer LS to control the oxide semiconductor layer OS1. When a voltage is applied to the light shielding layer LS, the light shielding layer LS and the gate electrode GL1-1 may be connected in the peripheral region of the pixel circuit. In a plan view, the opening GCON is provided so as not to overlap the light shielding layer LS.

### [4-3. Configuration of Transistor Tr2]

The transistor Tr2 includes a p-type transistor Tr2-1 and an n-type transistor Tr2-2. For example, although the transistor Tr2 is a transistor including polycrystalline silicon (poly-Si), the transistor Tr2 is not limited thereto.

Each of the p-type transistor Tr2-1 and the n-type transistor Tr2-2 has a gate electrode GL2, a gate insulating layer GI2, and semiconductor layers S1, S2, and S3 (hereinafter, they may be referred to as a “semiconductor layer S” when they are not particularly distinguished). The semiconductor layer S is provided below the oxide semiconductor layer OS. When the transistor Tr2 is a transistor including polycrystalline silicon, the semiconductor layer S contains silicon. The gate electrode GL2 faces the semiconductor layer S. The gate insulating layer GI2 is provided between the semiconductor layer S and the gate electrode GL2. In the present embodiment, although a bottom-gate transistor in which the gate electrode GL2 is provided closer to the substrate SUB than the semiconductor layer S is exemplified, a top-gate transistor in which the positional relationship between the semiconductor layer S and the gate electrode GL2 is reversed may also be used.

The semiconductor layer S of the p-type transistor Tr2-1 includes semiconductor layers S1 and S2. The semiconductor layer S of the n-type transistor Tr2-2 includes semiconductor layers S1, S2, and S3. The semiconductor layer S1 is a semiconductor layer in a region that overlaps the gate electrode GL2 in a planar view. The semiconductor layer S1 functions as a channel of the transistor Tr2-1. The semiconductor layer S2 functions as a conductive layer. The semiconductor layer S3 functions as a conductive layer with a higher resistance than the semiconductor layer S2. The semiconductor layer S3 suppresses hot carrier degradation by reducing hot carriers that enter the semiconductor layer S1.

The insulating layer IL1 and the gate insulating layer GI1 are provided on the semiconductor layer S. In the transistor Tr2, the gate insulating layer GI1 simply functions as an interlayer film. A wiring W2 is provided on these insulating layers. The wiring W2 is connected to the semiconductor layer S via an opening provided in the insulating layer IL1 and the gate insulating layer GI1. The insulating layer IL2 is provided on the wiring W2. The wiring W1 is provided on the insulating layer IL2. The wiring W1 is connected to the wiring W2 via an opening provided in the insulating layer IL2.

The gate electrode GL2 and the light shielding layer LS2 are in the same layer. The wiring W2 and the gate electrode GL1-1 are in the same layer. The term “in the same layer” means that a plurality of members are formed by patterning one layer.

### [4-4. Planar Layout of Array Substrate 300]

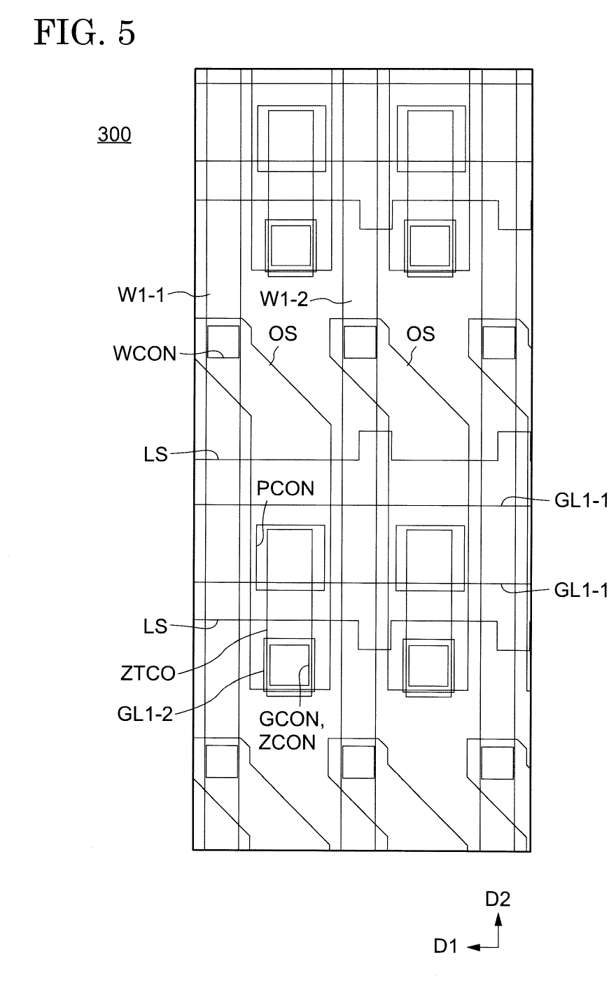

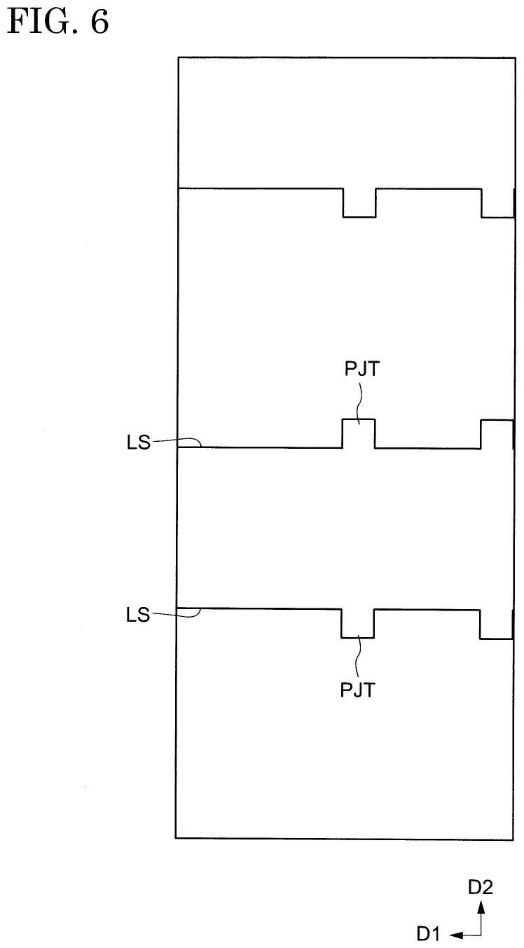

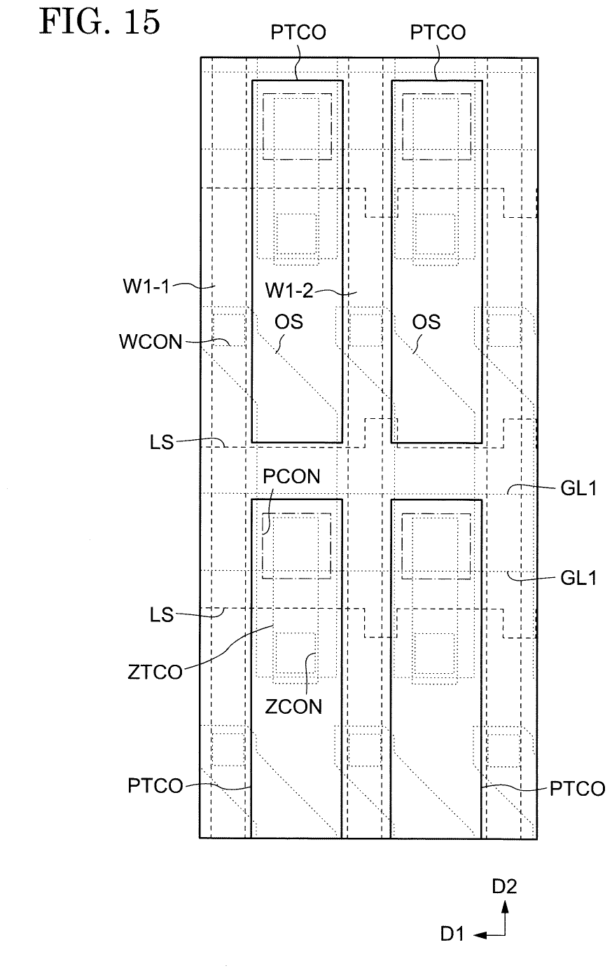

FIG. 5 is a schematic plan view showing a configuration of the array substrate 300 of the display device 10 according to an embodiment of the present invention. Each of FIGS. 6 to 17 is a plan view illustrating a layout of each layer in the array substrate 300 of the display device 10 according to an embodiment of the present invention. The pixel electrodes PTCO, the common auxiliary electrode CMTL, the common electrodes CTCO, and the spacer SP are omitted in FIG. 5. The planar layouts of the pixel electrodes PTCO, the common auxiliary electrode CMTL, and the common electrode CTCO are shown in FIGS. 15 to 17, respectively.

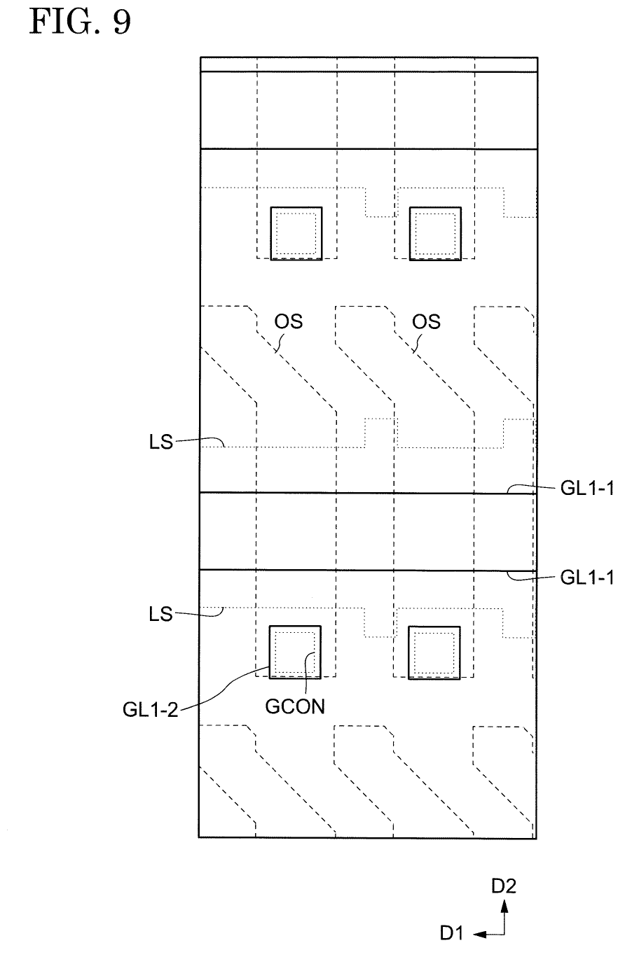

As shown in FIGS. 5 and 6, the light shielding layer LS extends in the first direction D1 and is provided in common to the pixels arranged in the first direction D1. The shape of the light shielding layer LS differs depending on the pixel. In the present embodiment, a protrusion portion PJT is provided that protrudes in the second direction D2 orthogonal to the first direction D1 from a part of the light shielding layer LS extending in the first direction D1. As shown in FIG. 9, the light shielding layer LS is provided in a region including a region where the gate electrode GL1-1 and the oxide semiconductor layer OS overlap each other in a plan view. The gate electrode GL1-1 can also be referred to as a “gate line.”

As shown in FIGS. 5, 7, and 9, the oxide semiconductor layer OS extends in the second direction D2. The gate electrode GL1-1 extends in the first direction D1 and intersects the oxide semiconductor layer OS. The pattern of the gate electrode GL1-1 is provided inside the pattern of the light shielding layer LS.

As shown in FIGS. 5, 8, and 9, the opening GCON is provided in the vicinity of the lower end of the pattern of the oxide semiconductor layer OS. The opening GCON is provided in a region that overlaps the pattern of the oxide semiconductor layer OS and does not overlap the gate electrode GL1-1. The opening GCON is provided in a region that overlaps the connection electrode GL1-2. The connection electrode GL1-2 has an island-shaped pattern that covers the opening GCON and overlaps the oxide semiconductor layer OS. Therefore, the connection electrode GL1-2 is in contact with the oxide semiconductor layer OS via the opening GCON.

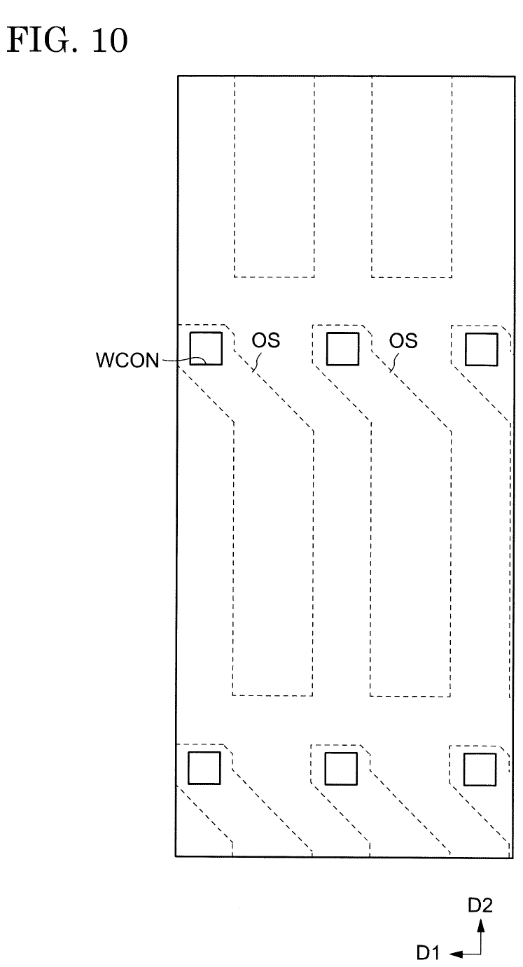

As shown in FIGS. 5 and 10, the opening WCON is provided in the vicinity of the upper end of the pattern of the oxide semiconductor layer OS in a region that overlaps the wiring W1. A main portion of the pattern of the oxide semiconductor layer OS extends in the second direction D2 between adjacent wirings W1. The remaining portion of the pattern of the oxide semiconductor layer OS extends from the main portion toward the region of the opening WCON in a direction oblique to the first direction D1 and the second direction D2.

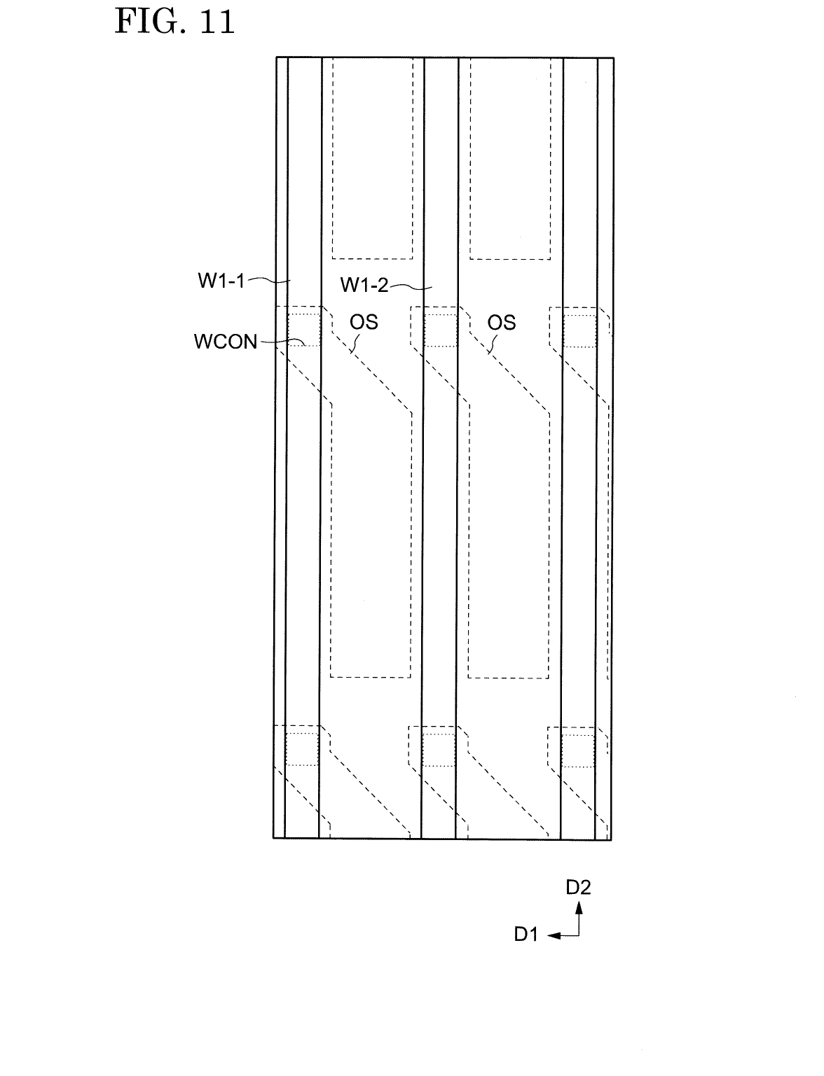

As shown in FIGS. 5 and 11, the plurality of wirings W1 extend in the second direction D2. When two adjacent wirings W1 are distinguished, the two adjacent wirings W1 are referred to as a “first wiring W1-1” and a “second wiring W1-2,” respectively. In this case, it can be said that the main portion of the oxide semiconductor layer OS extends in the second direction D2 between the first wiring W1-1 and the second wiring W1-2 and intersects the gate electrode GL1-1.

As shown in FIGS. 5, 12, and 13, the opening ZCON is provided in the vicinity of the lower end of the pattern of the oxide semiconductor layer OS. The opening ZCON is provided in a region that overlaps the pattern of the oxide semiconductor layer OS and does not overlap the gate electrode GL1-1. The opening ZCON is provided in a region that overlaps the connection electrodes GL1-2 and ZTCO. The connection electrode ZTCO overlaps the opening ZCON and the connection electrode GL1-2 between the first wiring W1-1 and the second wiring W1-2. Therefore, the connection electrode ZTCO is in contact with the connection electrode GL1-2 via the opening ZCON. In addition, the connection electrode ZTCO is not in contact with the oxide semiconductor layer OS.

As shown in FIGS. 5, 14, and 15, the opening PCON is provided in the vicinity of the upper end of the pattern of the connection electrode ZTCO. The opening PCON is provided in a region that overlaps the pattern of the gate electrode GL1-1 and the pattern of the connection electrode ZTCO. The opening PCON is provided in a region that overlaps the pixel electrode PTCO. The pixel electrode PTCO overlaps the gate electrode GL1-1, the oxide semiconductor layer OS, and the connection electrode ZTCO between the first wiring W1-1 and the second wiring W1-2. Therefore, the pixel electrode PTCO is in contact with the connection electrode ZTCO via the opening PCON that overlaps the gate electrode GL1-1.

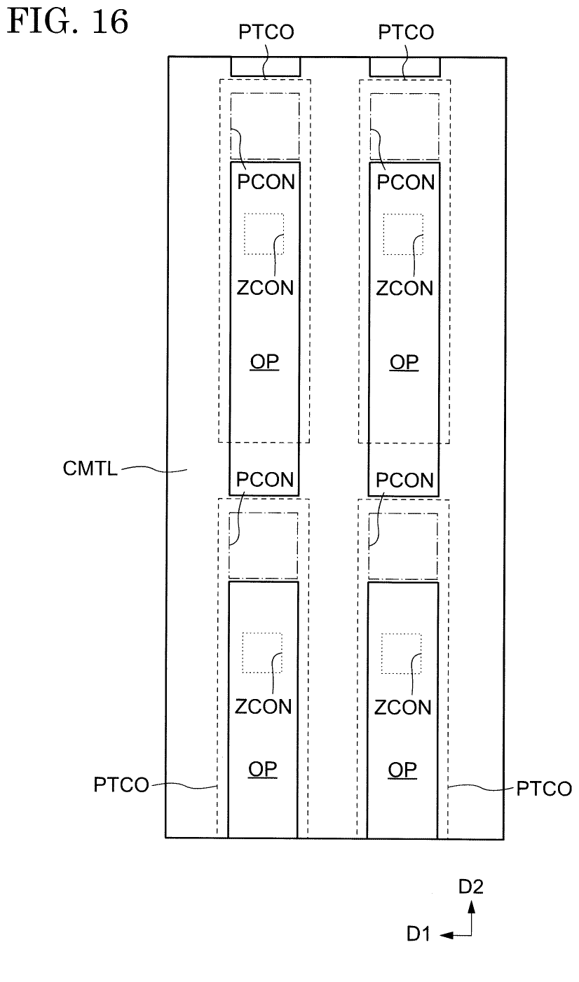

As shown in FIG. 16, the common auxiliary electrode CMTL is provided in a grid pattern so as to overlap a portion of the pixel electrode PTCO of each of the plurality of pixels, and an opening OP is formed at a position facing each pixel electrode PTCO. Specifically, the common auxiliary electrode CMTL is provided in common to the plurality of pixels without being divided at least within the image display region, overlaps not only the opening PCON of each pixel but also a portion of the edge portion of each pixel electrode PTCO. Therefore, the common auxiliary electrode CMTL overlaps the pixel electrode PTCO in the opening PCON. Further, the common auxiliary electrode CMTL also overlaps the gate electrode GL1-1 in a planar view. Meanwhile, the common auxiliary electrode CMTL is opened so that the pixel electrode PTCO including the opening ZCON is exposed. In other words, the opening ZCON (a first contact region CON1) is included in the display region. In addition, the display region here refers to a region where a user can view light from each pixel when viewed pixel by pixel. For example, a region that is shielded by a metal layer and through which the user cannot see light is not included in the display region. In other words, the display region may be referred to as a “light transmitting region (or an opening region).”

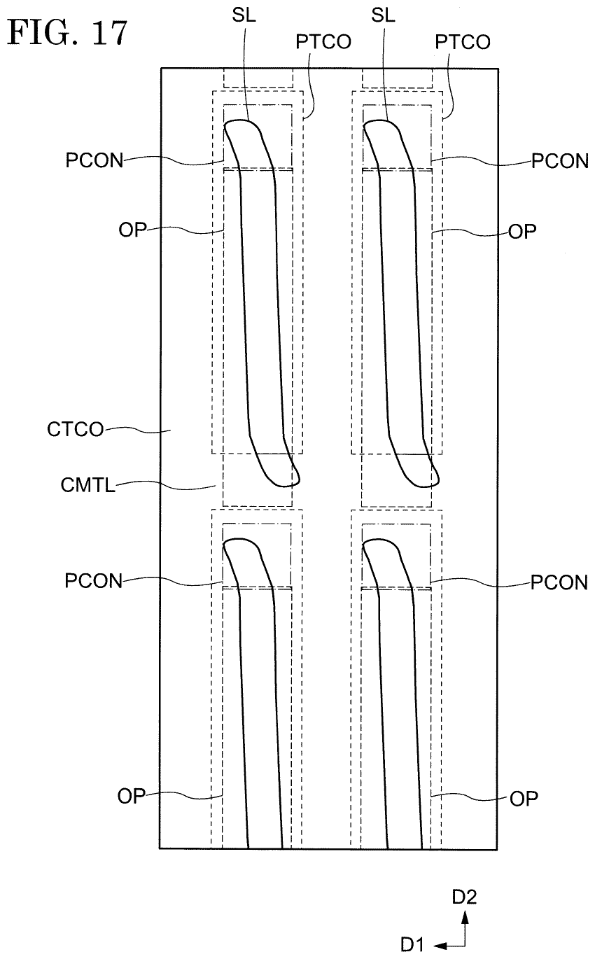

As shown in FIG. 17, the common electrode CTCO is provided in common to the plurality of pixels without being divided at least within the image display region. The common electrode CTCO overlaps the pixel electrode PTCO. The common electrode CTCO has a slit SL provided in a region corresponding to each of the openings OP. The slit SL has a curved shape (a vertically long S-shape). The tips of the slit SL have a shape in which the width perpendicular to the extension direction of the tip becomes smaller. Further, one tip of the slit SL overlaps the common auxiliary electrode CMTL within the opening PCON and also overlaps the pixel electrode PTCO. Furthermore, although the other tip of the slit SL is located within the opening OP, the other tip does not overlap the pixel electrode PTCO.

### [4-5. Materials of Each Component of Array Substrate 300]

A rigid substrate having light transmittance and no flexibility, such as a glass substrate, a silica substrate, and a sapphire substrate can be used as the substrate SUB. On the other hand, in the case where the substrate SUB needs to have flexibility, a flexible substrate containing a resin and having flexibility, such as a polyimide substrate, an acrylic substrate, a siloxane substrate, or a fluororesin substrate can be used as the substrate SUB. In order to improve the heat resistance of the substrate SUB, impurities may be introduced into the above resin.

A metal material can be used for the gate electrodes GL1 and GL2, the connection electrode GL1-2, the wirings W1 and W2, the light shielding layer LS, and the common auxiliary electrode CMTL. For example, aluminum (Al), titanium (Ti), chromium (Cr), cobalt (Co), nickel (Ni), molybdenum (Mo), hafnium (Hf), tantalum (Ta), tungsten (W), bismuth (Bi), or silver (Ag), or alloys or compounds thereof is used as the metal material. The above metal material may be used in a single layer or a stacked layer as the members of the above electrodes and the like.

For example, a stacked structure of Ti/Al/Ti is used for the gate electrode GL1-1 and the connection electrode GL1-2. In the present embodiment, the cross-sectional shape of a pattern end of the gate electrode GL1-1 and the connection electrode GL1-2 having the above stacked structure is a forward taper shape.

An insulating material can be used for the gate insulating layers GI1 and GI2, and the insulating layers IL1 to IL5. For example, inorganic insulating layers such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), or the like can be used as the insulating material. A low-defect insulating layer can be used as these insulating layers. An organic insulating material such as a polyimide resin, an acrylic resin, an epoxy resin, a silicone resin, a fluororesin, or a siloxane resin can be used for the insulating layer IL4. The above insulating material may be used in a single layer or a stacked layer as the members of the above insulating layers and the like.

SiOₓ with a thickness of 100 nm is used for the gate insulating layer GI1 as an example of the above insulating layer. SiOₓ/SiNₓ/SiOₓ with a total thickness of 600 nm to 700 nm is used for the insulating layer IL1. SiOₓ/SiNₓ with a total thickness of 60 nm to 100 nm is used for the gate insulating layer GI2. SiOₓ/SiNₓ/SiOₓ with a total thickness of 300 nm to 500 nm is used for the insulating layer IL2. SiOₓ (single layer), SiNₓ (single layer), or a stacked layer thereof with a total thickness of 200 nm to 500 nm is used for the insulating layer IL3. Polyimide resin with a thickness of 2 μm to 4 μm is used for the insulating layer IL4. SiNₓ (single layer) with a thickness of 50 nm to 150 nm is used for the insulating layer IL5.

Here, SiOₓN_{y} and AlOₓN_{y} are a silicon compound and an aluminum compound which contain nitrogen (N) in a smaller ratio (x>y) than oxygen (O). SiNₓO_{y} and AlNₓO_{y} are a silicon compound and an aluminum compound which contain oxygen in a smaller ratio (x>y) than nitrogen.

An oxide semiconductor having semiconductor characteristics can be used for the oxide semiconductor layer OS. The oxide semiconductor layer OS has light transmittance. For example, an oxide semiconductor containing indium (In), gallium (Ga), zinc (Zn), and oxygen (O) can be used for the oxide semiconductor layer OS. In particular, an oxide semiconductor having a composition ratio of In:Ga:Zn:O=1:1:1:4 can be used. However, the oxide semiconductor containing In, Ga, Zn, and O used in the present embodiment is not limited to the above composition, and an oxide semiconductor having a composition different from that described above can also be used. For example, the ratio of In may be larger than that described above to improve mobility. The ratio of Ga may be larger to increase the band gap and reduce the influence of light irradiation.

Other elements may be added to the oxide semiconductor containing In, Ga, Zn, and O. For example, a metal element such as Al or Sn may be added to the oxide semiconductor. In addition to the oxide semiconductor described above, an oxide semiconductor containing In and Ga (IGO), an oxide semiconductor containing In and Zn (IZO), an oxide semiconductor containing In, Sn, and Zn (ITZO), and an oxide semiconductor containing In and W may be used as the oxide semiconductor layer OS. The oxide semiconductor layer OS may be amorphous or crystalline. The oxide semiconductor layer OS may be a mixed phase of amorphous and crystalline.

A transparent conductive layer is used as the connection electrode ZTCO, the pixel electrode PTCO, and the common electrode CTCO. A mixture of indium oxide and tin oxide (ITO) and a mixture of indium oxide and zinc oxide (IZO) can be used for the transparent conductive layer. Materials other than the above materials may be used for the transparent conductive layer.

In general, when moisture (or hydrogen) entering from the outside diffuses into the channel region of an OS transistor, the OS transistor exhibits depletion-type transistor characteristics. After extensive research, the inventors have discovered that a transparent conductive oxide film in contact with a planarization film facilitates the diffusion of water contained in the planarization film. That is, when an oxide semiconductor layer and a planarization film are connected to each other via a conductive oxide film, the conductive oxide film functions as a water diffusion path, allowing water contained in the planarization film to diffuse through the conductive oxide film and reach the oxide semiconductor layer. Further, the inventors have discovered that a metal film in contact with the conductive oxide film functions as a so-called water-blocking layer, which is blocked to diffuse water.

In the array substrate 300 of the display device 10, the connection electrode ZTCO, which is electrically connected to the pixel electrode PTCO and is in contact with the insulating layer IL4 functioning as a planarization film, contains a transparent conductive oxide. Therefore, a heat treatment performed in the manufacturing process of the display device 10 after the insulating layer IL4 is formed causes water contained in the insulating layer IL4 to diffuse into the connection electrode ZTCO. However, the oxide semiconductor layer OS (more specifically, the oxide semiconductor layer OS2) is electrically connected to the connection electrode ZTCO via the connection electrode GL1-2 containing a metal material. That is, the oxide semiconductor layer OS is not in contact with the insulating layer IL4. Further, the connection electrode GL1-2 functions as a water-blocking layer. Therefore, since the diffusion of water from the insulating layer IL4 to the oxide semiconductor layer OS is blocked, variations in the transistor characteristics of the OS transistors in the display device 10 are suppressed. As a result, since the variations in the transistor characteristics of the plurality of OS transistors included in the display device 10 are also reduced, the manufacturing yield of the display device 10 is improved.

The display device 10 according to the present embodiment is a high-definition display device having a configuration in which the opening PCON in an insulating layer IL4, in which a pixel electrode PTCO is provided, is provided so as to overlap the gate electrode GL1-2. Since such a high-definition display device requires high transmittance, the configuration of the array substrate 300 in which many transparent conductive oxide films are disposed is particularly effective. Further, it goes without saying that the configuration of the array substrate 300 is effective not only for application to a high-definition display device, but also for application to a transparent display device requiring high transmittance.

### Second Embodiment

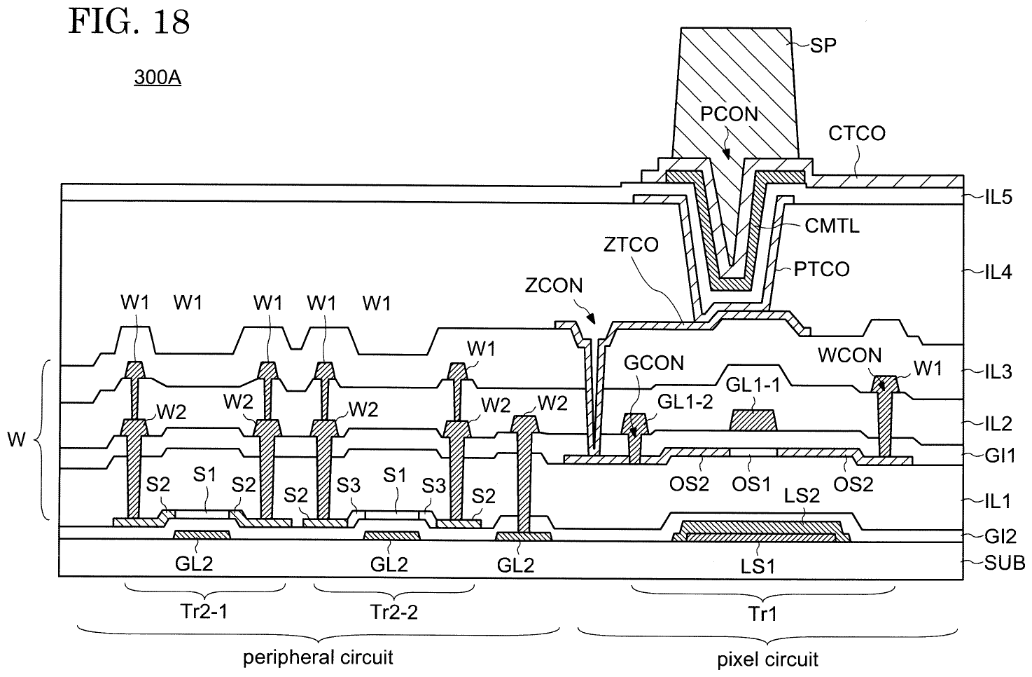

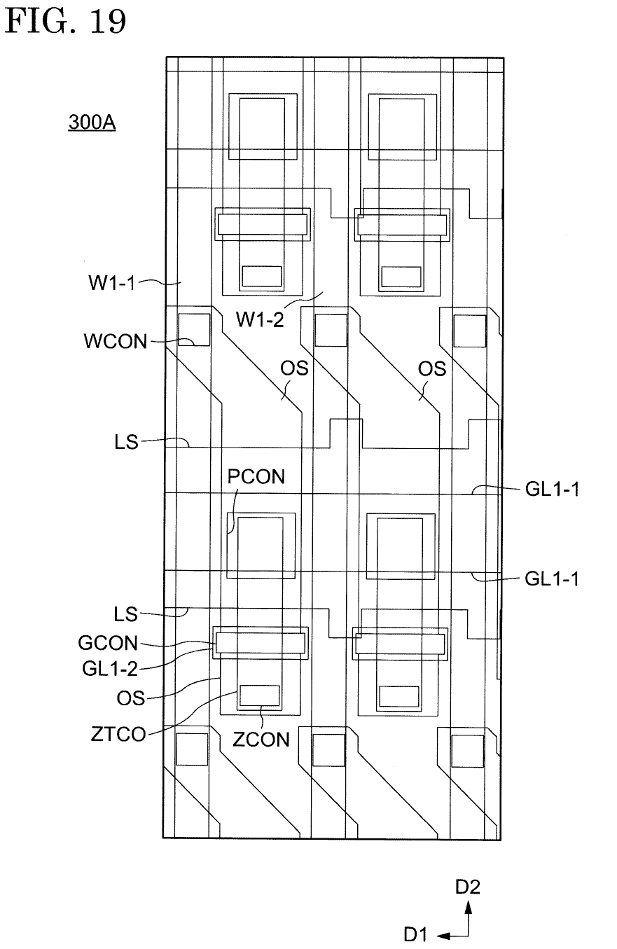

A configuration of an array substrate 300A of the display device 10 according to an embodiment of the present invention is described with reference to FIGS. 18 and 19. In the following description, when the configuration of the array substrate 300A is similar to the configuration of the array substrate 300 of the First Embodiment, the description of the configuration may be omitted.

FIG. 18 is a schematic cross-sectional view showing a configuration of the array substrate 300A of the display device 10 according to an embodiment of the present invention. FIG. 19 is a schematic plan view showing a configuration of the array substrate 300A of the display device 10 according to an embodiment of the present invention.

In the array substrate 300A, an opening GCON is provided in the gate insulating layer GI1 and the oxide semiconductor layer OS2 so as to separate the oxide semiconductor layer OS2 into two regions. One of the separated regions of the oxide semiconductor layer OS2 (hereinafter, referred to as a “first region of the oxide semiconductor layer OS2”) is connected to the oxide semiconductor layer OS1. The oxide semiconductor layer OS2 is exposed at the side of the opening GCON, and the insulating layer IL1 is exposed at the bottom of the opening GCON. Further, in the array substrate 300A, an opening ZCON is provided in the insulating layers IL3 and IL2 and the gate insulating layer GI1. The other separated region of the oxide semiconductor layer OS2 (hereinafter, referred to as a “second region of the oxide semiconductor layer OS2”) is exposed at the bottom of the opening ZCON.

In a plan view, the connection electrode GL1-2, which is formed as the same layer as the gate electrode GL1-1, is provided so as to cover the opening GCON. Since not only the side surface of the first region of the oxide semiconductor layer OS2 but also the side surface of the second region of the oxide semiconductor layer OS2 are exposed at the side of the opening GCON, the connection electrode GL1-2 is electrically connected to the first and second regions of the oxide semiconductor layer OS2 via the opening GCON. That is, the first and second regions of the oxide semiconductor layer OS2, which are separated by the opening GCON, are electrically connected to each other via the connection electrode GL1-2. In other words, the connection electrode GL-2 spatially separates the first and second regions of the oxide semiconductor layer OS2 and electrically connects the first and second regions of the oxide semiconductor layer OS2.

Further, in a plan view, the connection electrode ZTCO formed on the insulating layer IL3 is provided so as to cover the opening ZCON. That is, the connection electrode ZTCO is electrically connected to the second region of the oxide semiconductor layer OS2 via the opening ZCON. Although the connection electrode ZTCO is electrically connected to the pixel electrode PTCO, the connection electrode ZTCO is in contact with the insulating layer IL4 containing an organic insulating material. Therefore, water contained in the insulating layer IL4 is diffused into the connection electrode ZTCO by a heat treatment performed in the manufacturing process of the display device 10 after the insulating layer IL4 is formed.

In the array substrate 300A, the connection electrode ZTCO is in contact with the second region of the oxide semiconductor layer OS2. Therefore, water contained in the insulating layer IL4 passes through the connection electrode ZTCO and diffuses into the second region of the oxide semiconductor layer OS2. However, the first region and the second region of the oxide semiconductor layer OS2 are not in direct contact with each other, and the connection electrode GL1-2 containing a metal material is provided between them. Therefore, even when water contained in the insulating layer IL4 diffuses into the second region of the oxide semiconductor layer OS2, it is blocked by the connection electrode GL1-2, and hardly diffuses into the first region of the oxide semiconductor layer OS2. In other words, in the array substrate 300A as well, the connection electrode GL1-2 can function as a water-blocking layer.

As described above, in the array substrate 300A of the display device 10 according to the present embodiment, the oxide semiconductor layer OS2 is separated into two regions by the connection electrodes GL1-2, and thus the connection electrode GL1-2 blocks the diffusion of water contained in the insulating layer IL4. Thus, the water contained in the insulating layer IL4 does not diffuse into the oxide semiconductor layer OS1. Therefore, since the diffusion of water from the insulating layer IL4 to the oxide semiconductor layer OS1, which functions as a channel region, is blocked, the variations in the transistor characteristics of the OS transistor are suppressed in the display device 10 according to the present embodiment as well. As a result, since the variations in the transistor characteristics of the plurality of OS transistors included in the display device 10 are also reduced, the manufacturing yield of the display device 10 is improved.

In addition, although the configuration in which the oxide semiconductor layer OS2 is separated into two regions is described in the present embodiment, the number of regions into which the oxide semiconductor layer OS2 is separated may be at least two or more.

### Third Embodiment

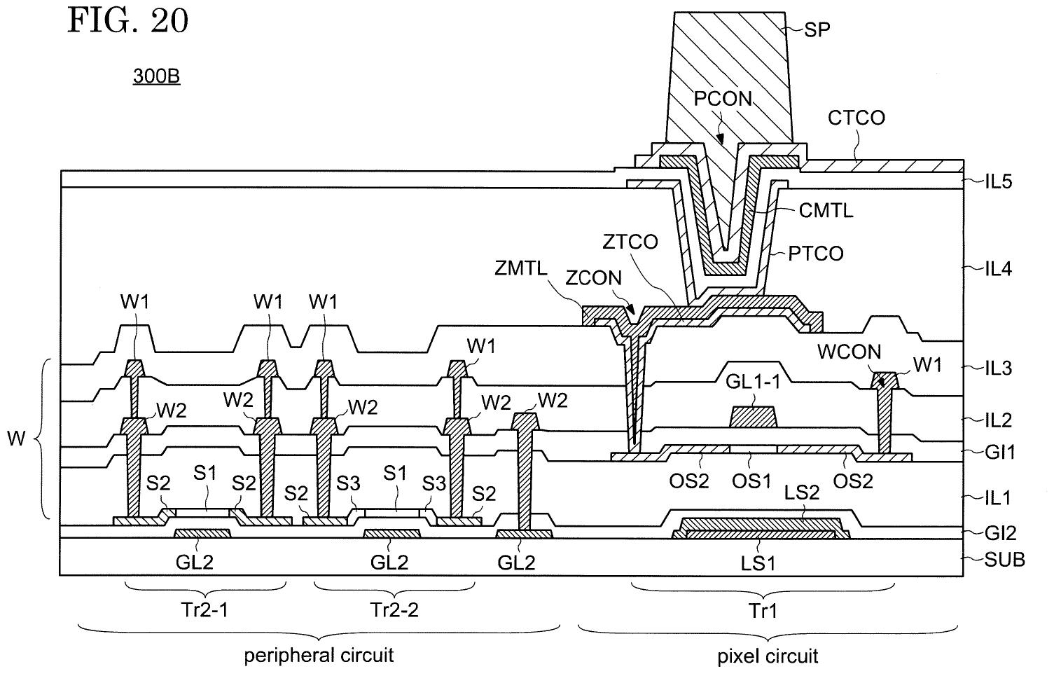

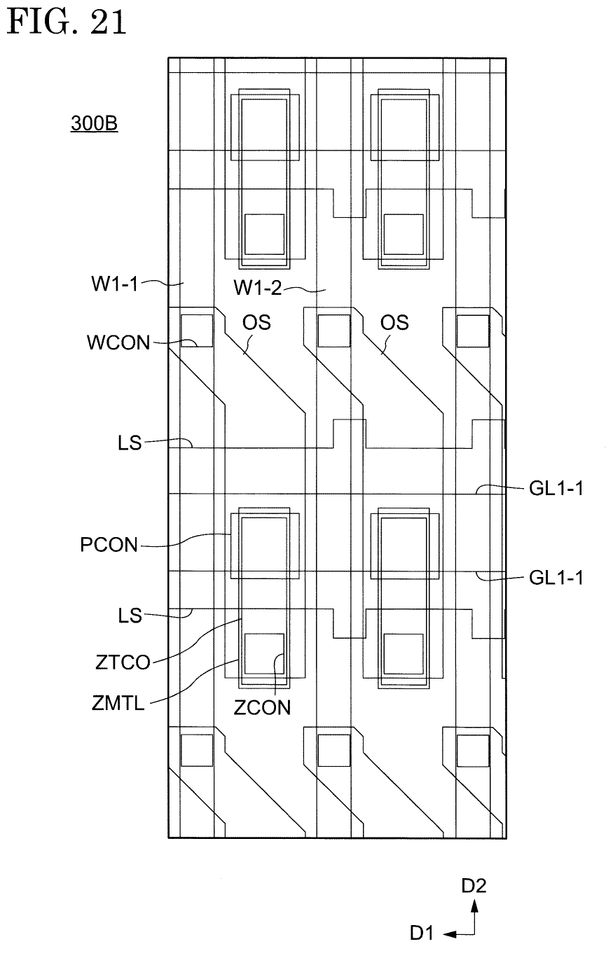

A configuration of an array substrate 300B of the display device 10 according to an embodiment of the present invention is described with reference to FIGS. 20 and 21. In the following description, when the configuration of the array substrate 300B is similar to the configuration of the array substrate 300 of the First Embodiment or the array substrate 300A of the Second Embodiment, the description of the configuration may be omitted.

FIG. 20 is a schematic cross-sectional view showing a configuration of the array substrate 300B of the display device 10 according to an embodiment of the present invention. FIG. 21 is a schematic plan view showing a configuration of the array substrate 300B of the display device 10 according to an embodiment of the present invention.

Unlike the array substrates 300 and 300A, the array substrate 300B does not include an opening GCON in the gate insulating layer GI1 and the oxide semiconductor layer OS2. Further, similar to the array substrate 300A, the array substrate 300B includes the opening ZCON in the insulating layers IL3 and IL2 and the gate insulating layer GI1. The array substrate 300B also includes the connection electrode ZMTL containing a metal material on the connection electrode ZTCO. More specifically, the connection electrode ZMTL is provided between the connection electrode ZTC0 and the pixel electrode PTCO, and electrically connects the connection electrode ZTCO and the pixel electrode PTCO.

In a plan view, since the connection electrode ZMTL formed on the connection electrode ZTCO in contact with the oxide semiconductor layer OS2 is provided so as to cover the connection electrode ZTCO, the connection electrode ZTCO is not in contact with the insulating layer IL4 containing an organic insulating material. That is, since the connection electrode ZTCO and the insulating layer IL4 are spatially separated by the connection electrode ZMTL in the array substrate 300B, water contained in the insulating layer IL4 is blocked by the connection electrode ZMTL and hardly diffuses into the connection electrode ZTCO. Thus, the connection electrode ZMTL can function as a water-blocking layer in the array substrate 300B.

As described above, in the array substrate 300B of the display device 10 according to the present embodiment, the connection electrode ZMTL is provided so as to cover the connection electrodes ZTCO, and thus the connection electrodes ZTCO is not contact with the insulating layer IL4. Thus, water contained in the insulating layer IL4 does not diffuse into the connection electrode ZMTL in contact with the oxide semiconductor layer OS1. Therefore, since the diffusion of water from the insulating layer IL4 to the oxide semiconductor layer OS1 is blocked, the variations in the transistor characteristics of the OS transistor are suppressed even in the display device 10 according to the present embodiment. As a result, since the variations in the transistor characteristics of the plurality of OS transistors included in the display device 10 are also reduced, the manufacturing yield of the display device 10 is improved.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on the display device of each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A display device, comprising:
a gate electrode;
an oxide semiconductor layer overlapping the gate electrode;
a first insulating layer containing an organic insulating material over the oxide semiconductor layer;
a pixel electrode over the first insulating layer;
a first connection electrode electrically connected to the pixel electrode and in contact with the first insulating layer; and
a second connection electrode electrically connecting the oxide semiconductor layer and the first connection electrode, and provided between the oxide semiconductor layer and the first connection electrode,
wherein the first connection electrode contains a transparent conductive oxide, and
wherein the second connection electrode contains a metal material.

2. The display device according to claim 1, wherein the second connection electrode is a same layer as the gate electrode.

3. The display device according to claim 1, further comprising a transistor including a semiconductor layer provided below the oxide semiconductor layer.

4. The display device according to claim 3, wherein the semiconductor layer contains silicon.

5. A display device, comprising:
a gate electrode;
an oxide semiconductor layer overlapping the gate electrode;
a first insulating layer containing an organic insulating material over the oxide semiconductor layer;
a pixel electrode over the first insulating layer; and
a first connection electrode in contact with the first insulating layer, and connecting the oxide semiconductor layer and the pixel electrode,
wherein the oxide semiconductor layer is separated into at least two regions between the gate electrode and the first connection electrode,
wherein the at least two regions are electrically connected to each other through a second connection electrode,
wherein the first connection electrode contains a transparent conductive oxide, and
wherein the second connection electrode contains a metal material.

6. The display device according to claim 5, wherein the second connection electrode is a same layer as the gate electrode.

7. The display device according to claim 5, further comprising a transistor including a semiconductor layer provided below the oxide semiconductor layer.

8. The display device according to claim 7, wherein the semiconductor layer contains silicon.

9. A display device, comprising:
a gate electrode;
an oxide semiconductor layer overlapping the gate electrode;
a first insulating layer containing an organic insulating material over the oxide semiconductor layer;
a pixel electrode over the first insulating layer;
a first connection electrode in contact with the first insulating layer; and
a second connection electrode covering the first connection electrode so that the first connection electrode is not in contact with the first insulating layer, and electrically connecting the first connection electrode and the pixel electrode,
wherein the first connection electrode contains a transparent conductive oxide, and
wherein the second connection electrode contains a metal material.

10. The display device according to claim 9,
wherein the first insulating layer comprises an opening where the pixel electrode is provided, and
wherein in a plan view, the opening overlaps the gate electrode.

11. The display device according to claim 9, further comprising:
a gate insulating layer between the gate electrode and the oxide semiconductor layer;
a second insulating layer over the gate electrode, and
a wiring in contact with the oxide semiconductor layer through an opening provided in the second insulating layer and the gate insulating layer, over the second insulating layer.

12. The display device according to claim 11, wherein the wiring contains a metal material.

13. The display device according to claim 11, wherein the wiring is not in contact with the first insulating layer.

14. The display device according to claim 9, further comprising a transistor including a semiconductor layer provided below the oxide semiconductor layer.

15. The display device according to claim 14, wherein the semiconductor layer contains silicon.
